(19) United States
(12) Patent Application Publication
(10) Pub. No.: US 2026/0372004 A1
(43) Pub. Date: Nov. 19, 2026

(54) SUBSTRATE PROCESSING APPARATUS AND METHOD OF DETECTING INTERNAL STATUS OF PROCESSING CONTAINER

(71) Applicant: Tokyo Electron Limited, Tokyo (JP)

(72) Inventors: Shota UMEZAKI, Koshi City, Kumamoto (JP); Mitsuki TERUI, Koshi City, Kumamoto (JP); Shigeru MORIYAMA, Koshi City, Kumamoto (JP)

(21) Appl. No.: 19/410,032

(22) Filed: Dec. 5, 2025

(30) Foreign Application Priority Data
Dec. 6, 2024 (JP) 2024-213350

(51) Int. Cl. H10P 72/30; H10P 72/00; H10P 72/50

(52) U.S. Cl. CPC H10P 72/3406; H10P 72/0616; H10P 72/3411; H10P 72/53

(57) ABSTRACT

A substrate processing apparatus includes: a processing container including a processing space capable of accommodating a substrate and a loading/unloading port through which the substrate is loaded into or unloaded from the processing space; a lid configured to be capable of closing the loading/unloading port; and an imager configured to capture an image of an imaging region including the loading/unloading port and the processing space within the processing container exposed from the loading/unloading port, in a state where the loading/unloading port is not closed by the lid.

### CROSS-REFERENCE TO RELATED APPLICATION

This application is based upon and claims the benefit of priority from Japanese Patent Application No. 2024-213350, filed on Dec. 6, 2024, the entire contents of which are incorporated herein by reference.

### TECHNICAL FIELD

The present disclosure relates to a substrate processing apparatus and a method of detecting an internal status of a processing container.

### BACKGROUND

Patent Document 1 discloses a technique in which, when loading or unloading a substrate into or from a processing container, an optical system provided in a transport robot that transports the substrate is used to capture an image of the substrate, and a state of a liquid film on the substrate is detected based on an imaging result from the optical system.

### PRIOR ART DOCUMENTS

### Patent Documents

Patent Document 1: Japanese Patent Laid-Open Publication No. 2022-176901

### SUMMARY

According to one embodiment of the present disclosure, a substrate processing apparatus includes: a processing container including a processing space capable of accommodating a substrate and a loading/unloading port through which the substrate is loaded into or unloaded from the processing space; a lid configured to be capable of closing the loading/unloading port; and an imager configured to capture an image of an imaging region including the loading/unloading port and the processing space within the processing container exposed from the loading/unloading port, in a state where the loading/unloading port is not closed by the lid.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram illustrating a configuration of a substrate processing apparatus according to an embodiment.

FIG. 2 is a diagram illustrating a configuration of a liquid processing unit according to the embodiment.

FIG. 3 is a side cross-sectional view schematically illustrating a configuration of a drying unit according to the embodiment.

FIG. 4 is a side cross-sectional view schematically illustrating the configuration of the drying unit according to the embodiment.

FIG. 5 is a side cross-sectional view schematically illustrating the configuration of the drying unit according to the embodiment.

FIG. 6 is a cross-sectional view taken along line VI-VI in FIG. 3.

FIG. 7 is an enlarged view illustrating a configuration of an illuminator and its surroundings according to the embodiment.

FIG. 8 is a cross-sectional view taken along line VIII-VIII in FIG. 7.

FIG. 9 is a flowchart illustrating a sequence of a process executed by the substrate processing apparatus according to the embodiment.

FIG. 10 is a flowchart illustrating a sequence of a first processing-container internal-status detection process according to the embodiment.

FIG. 11 is a flowchart illustrating a sequence of a sealing member abnormality detection process according to the embodiment.

FIG. 12 is a flowchart illustrating a sequence of a second processing-container internal-status detection process according to the embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, a mode (hereinafter referred to as “embodiment”) for implementing a substrate processing apparatus and a method of detecting an internal status of a processing container according to the present disclosure is described in detail with reference to the drawings. In addition, the present disclosure is not limited by this embodiment. Further, various embodiments may be appropriately combined to the extent that the processing contents do not conflict with one another. Further, in the following embodiments, the same reference numerals are given to the same components, and redundant descriptions are omitted.

Further, in the embodiments described below, terms such as “constant”, “perpendicular”, “vertical”, or “parallel” may be used, but these terms do not necessarily require strict “constancy”, “perpendicularity”, “verticality”, or “parallelism”. That is, these terms are intended to allow for errors and tolerances in, for example, manufacturing accuracy, installation accuracy, and the like.

Further, in the drawings referenced below, to facilitate understanding of descriptions, a Cartesian coordinate system may be illustrated in which X-axis, Y-axis, and Z-axis directions are defined to be perpendicular to each other, and a positive Z-axis direction is defined as a vertically upward direction. Further, a rotational direction about a vertical axis may be referred to as “θ-direction”.

Patent Document 1 discloses a technique in which, when loading or unloading a substrate into or from a processing container, an optical system provided in a transport robot that transports the substrate is used to capture an image of the substrate, and a state of a liquid film on the substrate is detected based on an imaging result from the optical system.

However, if a substrate is loaded into the processing container while another substrate remains inside the processing container, there is a risk that the two substrates may collide, potentially causing damage to the substrates. Therefore, there is a demand for a technique to appropriately detect an internal status of the processing container.

### EMBODIMENT

### Configuration of Substrate Processing Apparatus

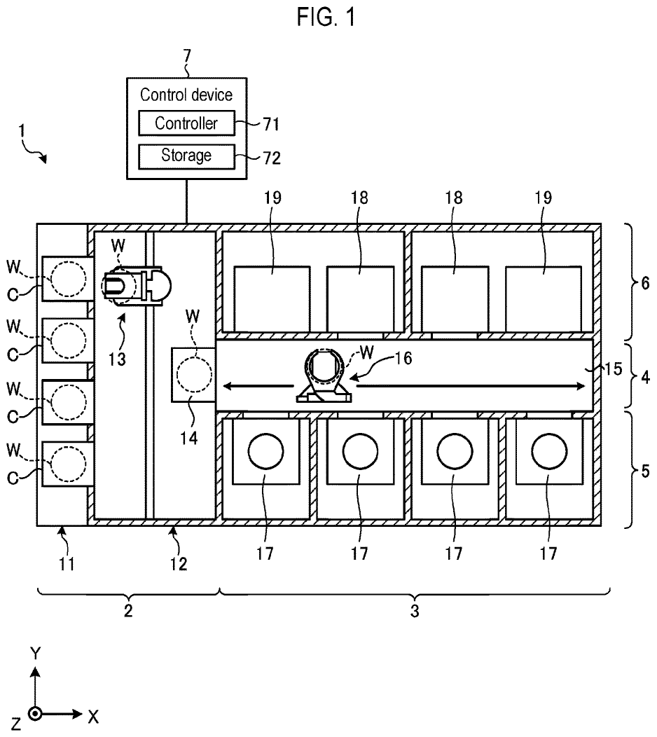

First, a configuration of a substrate processing apparatus according to an embodiment is described with reference to FIG. 1. FIG. 1 is a diagram illustrating the configuration of the substrate processing apparatus according to the embodiment.

As illustrated in FIG. 1, the substrate processing apparatus 1 includes a loading/unloading station 2 and a processing station 3. The loading/unloading station 2 and the processing station 3 are provided adjacent to each other.

The loading/unloading station 2 includes a carrier placement section 11 and a transport section 12. Carriers C, each accommodating semiconductor wafers (hereinafter referred to as the “wafers W”) in a horizontal state, are placed on the carrier placement section 11.

The transport section 12 is provided adjacent to the carrier placement section 11. A transport device 13 and a deliverer 14 are disposed in an interior of the transport section 12.

The transport device 13 includes a wafer holder that holds the wafer W. Further, the transport device 13 is capable of movement in both horizontal and vertical directions and of pivoting around a vertical axis. The transport device 13 transports the wafer W between the carriers C and the deliverer 14 by using the wafer holder.

The processing station 3 is provided adjacent to the transport section 12. The processing station 3 includes a transport block 4, a first processing block 5, and a second processing block 6.

The transport block 4 includes a transport area 15 and a transport device 16. The transport area 15 is, for example, a rectangular parallelepiped region extending along an arrangement direction (X-axis direction) of the loading/unloading station 2 and the processing station 3. The transport device 16 is disposed in the transport area 15.

The transport device 16 includes a wafer holder that holds the wafer W. The transport device 16 is capable of movement in both horizontal and vertical directions and of pivoting around a vertical axis. The transport device 16 transports the wafer W between the deliverer 14, the first processing block 5, and the second processing block 6 by using the wafer holder.

The first processing block 5 and the second processing block 6 are disposed adjacent to the transport area 15 on either side of the transport area 15. Specifically, the first processing block 5 is disposed on one side (side of a negative Y-axis direction) of the transport area 15 in a direction (Y-axis direction) perpendicular to the arrangement direction (X-axis direction) of the loading/unloading station 2 and the processing station 3. Further, the second processing block 6 is disposed on the other side (side of a positive Y-axis direction) of the transport area 15 in the direction (Y-axis direction) perpendicular to the arrangement direction (X-axis direction) of the loading/unloading station 2 and the processing station 3.

The first processing block 5 includes a liquid processing unit 17.

The liquid processing unit 17 performs a cleaning process to clean an upper surface of the wafer W, which is a patterned surface. Further, the liquid processing unit 17 performs a liquid film formation process to form a liquid film on the upper surface of the wafer W after the cleaning process. A configuration of the liquid processing unit 17 is described later.

The second processing block 6 includes a drying unit 18 and a supply unit 19.

The drying unit 18 performs a supercritical drying process on the wafer W after the liquid film formation process. Specifically, the drying unit 18 dries the wafer W by bringing the wafer W, which has undergone the liquid film formation process, into contact with a supercritical-state processing fluid (hereinafter also referred to as “supercritical fluid”). A configuration of the drying unit 18 is described later.

The supply unit 19 supplies the processing fluid to the drying unit 18. Specifically, the supply unit 19 includes a group of supply devices such as a flow-rate meter, a flow-rate adjuster, a back pressure valve, a heater, and others, and a housing that accommodates the supply device group. In the present embodiment, the supply unit 19 supplies CO₂ as the processing fluid to the drying unit 18.

The substrate processing apparatus 1 includes a control device 7. The control device 7 is, for example, a computer and includes a controller 71 and a storage 72.

The controller 71 includes a microcomputer including components such as a Central Processing Unit (CPU), Read Only Memory (ROM), Random Access Memory (RAM), and input/output ports, as well as various circuits. The CPU of the microcomputer reads and executes programs stored in the ROM, thereby controlling the transport devices 13 and 16, the liquid processing unit 17, the drying unit 18, the supply unit 19, and others.

The programs may be recorded on a non-transitory computer-readable recording medium, and may be installed from the recording medium into the storage 72 of the control device 7. Examples of the computer-readable recording medium may include hard disks (HD), flexible disks (FD), compact disks (CD), magneto-optical disks (MO), memory cards, and others.

The storage 72 is realized, for example, by semiconductor memory devices such as RAM, flash memory, and others, or by storage devices such as hard disks, optical disks, and others.

### Configuration of Liquid Processing Unit

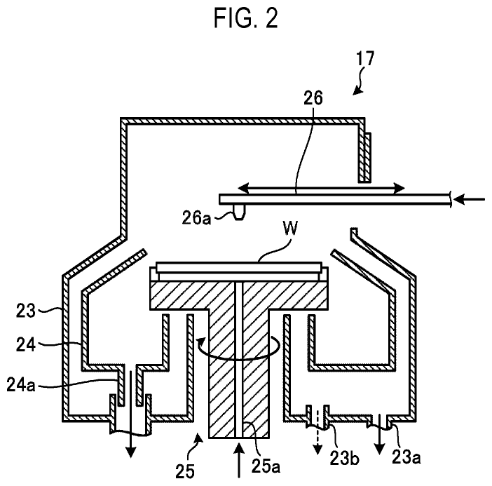

Next, a configuration of the liquid processing unit 17 is described with reference to FIG. 2. FIG. 2 is a diagram illustrating the configuration of the liquid processing unit 17 according to the embodiment. The liquid processing unit 17 is configured, for example, as a single-wafer cleaner that cleans the wafers W one by one by spin cleaning.

As illustrated in FIG. 2, the liquid processing unit 17 holds the wafer W substantially horizontally by using a wafer holder 25, which is located within an outer chamber 23 forming a processing space, and rotates the wafer W by rotating the wafer holder 25 around a vertical axis. Then, the liquid processing unit 17 advances a nozzle arm 26 above the rotating wafer W and supplies a chemical liquid and a rinse liquid in a predetermined order from a chemical liquid nozzle 26a provided at a tip end of the nozzle arm 26, thereby performing the cleaning process on a front surface of the wafer W.

In the liquid processing unit 17, a gas supply path 25a is formed in an interior of the wafer holder 25. The liquid processing unit 17 supplies a gas from the gas supply path 25a, for example, an inert gas such as a nitrogen gas and the like, to a rear surface center of the wafer W.

In the cleaning process, particles or organic contaminants are first removed using, for example, an alkaline chemical liquid such as an SC1 liquid (a mixture of ammonia and hydrogen peroxide), followed by a rinse with a rinse liquid such as deionized water (hereinafter referred to as “DIW”). Next, a natural oxide film is removed using an acidic chemical liquid such as a diluted hydrofluoric acid liquid (hereinafter referred to as “DHF”), followed by a rinse with DIW.

The aforementioned various chemical liquids are received in the outer chamber 23 or an inner cup 24 disposed inside the outer chamber 23, and are discharged from a drainage port 23a provided at a bottom of the outer chamber 23 and a drainage port 24a provided at a bottom of the inner cup 24. Further, an internal atmosphere of the outer chamber 23 is exhausted from an exhaust port 23b provided at the bottom of the outer chamber 23.

The liquid film formation process is performed after the rinse in the cleaning process. Specifically, the liquid processing unit 17 supplies an IPA liquid to both the front surface and rear surface of the wafer W while rotating the wafer holder 25. Therefore, the DIW remaining on either surface of the wafer W is replaced with the IPA.

At this time, the liquid processing unit 17 supplies a gas from the gas supply path 25a to the rear surface center of the wafer W. The gas supplied to the rear surface center of the wafer W flows along the rear surface of the wafer W toward a rear surface outer periphery of the wafer W. This may prevent the IPA supplied to the front surface of the wafer W from flowing to the rear surface of the wafer W during the liquid film formation process in the liquid processing unit 17. Thereafter, the liquid processing unit 17 gently stops the rotation of the wafer holder 25.

The wafer W, which has undergone the liquid film formation process and has an IPA liquid film formed on the front surface, is received by the transport device 16 by a gripper provided in the wafer holder 25 and is unloaded from the liquid processing unit 17. The liquid film formed on the wafer W prevents pattern collapse caused by evaporation (vaporization) of the liquid on the upper surface of the wafer W during the transport of the wafer W from the liquid processing unit 17 to the drying unit 18 or during the loading of the wafer into the drying unit 18.

### Configuration of Drying Unit

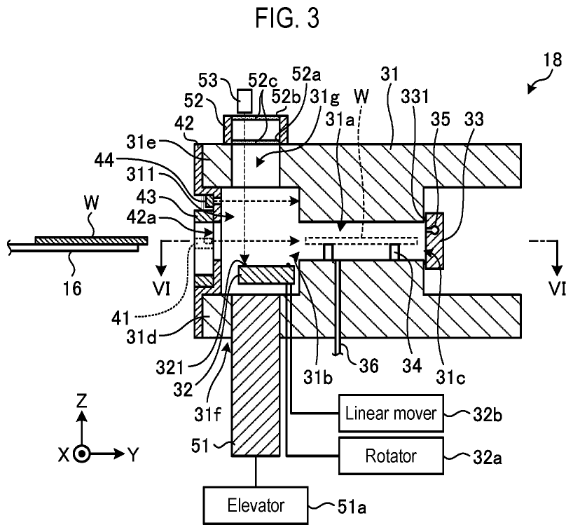

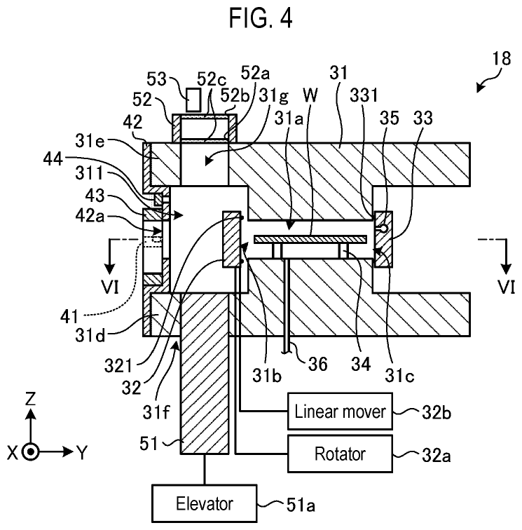

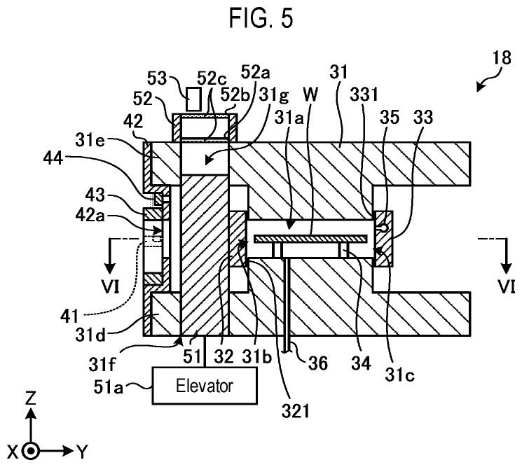

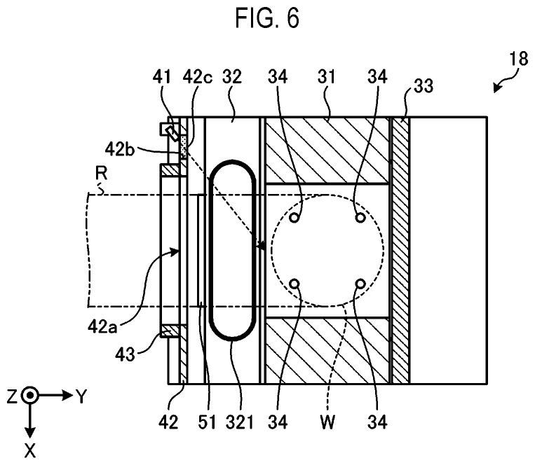

Next, a configuration of the drying unit 18 is described with reference to FIGS. 3 to 8. FIGS. 3 to 5 are side cross-sectional views schematically illustrating the configuration of the drying unit 18 according to the embodiment. FIG. 6 is a cross-sectional view taken along line VI-VI in FIG. 3. In addition, FIG. 3 illustrates a lid 32 located at a standby position, FIG. 4 illustrates the lid 32 located at an open position, and FIG. 5 illustrates the lid 32 located at a closed position.

As illustrated in FIGS. 3 to 5, the drying unit 18 includes a processing container 31, lids 32 and 33, and support pins 34.

The processing container 31 includes an internal processing space 31a capable of accommodating, for example, the wafer W having a diameter of 300 mm. In a supercritical drying process for the wafer W, the internal processing space 31a of the processing container 31 is pressurized.

The processing container 31 has, for example, a rectangular shape in a plane view, and on a side surface facing the transport area 15 among multiple (herein, four) side surfaces of the processing container 31, includes a loading/unloading port 31b, through which the wafer W is loaded into or unloaded from the processing space 31a. The processing container 31 includes a maintenance port 31c at a position facing the loading/unloading port 31b with the processing space 31a in between. The maintenance port 31c communicates the processing space 31a with an outside. The maintenance port 31c is used, for example, when performing maintenance of the processing container 31.

The lid 32 is disposed on one end side (side of the negative Y-axis direction) of the processing container 31 in a transport direction (Y-axis direction) of the wafer W.

The lid 32 is configured to be capable of closing the loading/unloading port 31b of the processing container 31. That is, the lid 32 is connected to a rotator 32a and a linear mover 32b. By means of the rotator 32a, it is possible for the lid 32 to rotate between the standby position illustrated in FIG. 3 and the open position illustrated in FIG. 4. By means of the linear mover 32b, it is possible for the lid 32 to move between the open position illustrated in FIG. 4 and the closed position illustrated in FIG. 5. This allows the lid 32 to open or close the loading/unloading port 31b. The closed position is a position where the lid 32 closes the loading/unloading port 31b via a sealing member 321. The open position is spaced apart from the closed position in an unloading direction (e.g., in the negative Y-axis direction) of the wafer W with respect to the processing space 31a. The standby position is a position where the lid 32 does not interfere with a transport path R (see FIG. 6) of the wafer W to the processing space 31a. When the lid 32 is located at the standby position, the loading/unloading port 31b is not closed by the lid 32, allowing the transport device 16 to load the held wafer W from the loading/unloading port 31b into the processing space 31a. Further, when the lid 32 is located at the standby position, a portion of the sealing member 321 faces a second insertion through-hole 31g to be described later. The sealing member 321 may be, for example, an O-ring.

The lid 33 is disposed on the other end side (side of the positive Y-axis direction) of the processing container 31 in the transport direction (Y-axis direction) of the wafer W. The lid 33 closes the maintenance port 31c of the processing container 31. The lid 33 closes the maintenance port 31c via a sealing member 331. The sealing member 331 may be, for example, an O-ring.

In this way, the processing space 31a is open at both ends in the transport direction of the wafer W, and the processing space 31a is sealed when both the loading/unloading port 31b and the maintenance port 31c are closed respectively by the lids 32 and 33.

The lid 33 is provided with a supply port 35. The supply port 35 is connected to a supply line (not illustrated) for supplying a supercritical fluid to the drying unit 18. Further, the processing space 31a is provided with a discharge port 36. The discharge port 36 is connected to a discharge line (not illustrated) for discharging the supercritical fluid and other fluids from the drying unit 18.

The supply port 35 is horizontally open toward the processing space 31a. The supercritical fluid supplied from the supply line (not illustrated) flows horizontally within the processing space 31a from the maintenance port 31c toward the loading/unloading port 31b.

The discharge port 36 is positioned near the loading/unloading port 31b. For example, the discharge port 36 may be formed at a bottom surface of the processing space 31a near the loading/unloading port 31b. The supercritical fluid, which has flowed through the processing space 31a toward the loading/unloading port 31b, is discharged from the discharge port 36 to the outside of the processing space 31a through the discharge line (not illustrated). In addition, the supercritical fluid discharged from the processing space 31a may contain the IPA liquid, which has been dissolved from the front surface of the wafer W into the supercritical fluid.

The support pins 34 are provided on the bottom surface of the processing space 31a to support the wafer W at a distance from the bottom surface of the processing space 31a.

In such a drying unit 18, the IPA liquid between patterns formed on the wafer W is gradually dissolved into the supercritical fluid by coming into contact with the supercritical fluid at a high pressure (e.g., 16 MPa), and a space between the patterns is gradually replaced with the supercritical fluid. Then, the space between the patterns is finally filled only with the supercritical fluid.

Then, after the IPA liquid between the patterns is removed, an internal pressure of the processing container 31 is reduced from the high pressure to the atmospheric pressure, whereby CO₂ may change from a supercritical state to a gaseous state, and the space between the patterns may be occupied only by a gas. In this way, the IPA liquid between the patterns is removed, and the drying process of the wafer W is completed.

In addition to having a lower viscosity compared to a liquid (e.g., IPA liquid) and a high ability to dissolve a liquid, the supercritical fluid has no interface existing between the supercritical fluid and a liquid or gas in equilibrium with the supercritical fluid. Thus, in the drying process using the supercritical fluid, the liquid may be dried without being affected by surface tension. Therefore, according to the embodiment, it is possible to prevent pattern collapse during the drying process.

In addition, the embodiment illustrates an example in which the IPA liquid is used as an anti-drying liquid and the supercritical-state CO₂ is used as the processing fluid, but a liquid other than IPA may be used as the anti-drying liquid, and a fluid other than the supercritical-state CO₂ may be used as the processing fluid.

The processing container 31 includes a first protrusion 31d and a second protrusion 31e, which protrude from the loading/unloading port 31b toward a side of the unloading direction (herein, the side of the negative Y-axis direction) of the wafer W with respect to the processing space 31a. The first protrusion 31d protrudes from below the loading/unloading port 31b toward the side of the negative Y-axis direction, and the second protrusion 31e protrudes from above the loading/unloading port 31b toward the side of the negative Y-axis direction.

The first protrusion 31d is formed with a first insertion through-hole 31f that penetrates through upper and lower surfaces of the first protrusion 31d. In addition, the second protrusion 31e is formed, at a position facing the first insertion through-hole 31f in the vertical direction, with a second insertion through-hole 31g that penetrates through upper and lower surfaces of the second protrusion 31e. A lock member 51 to be described later is inserted through the first insertion through-hole 31f and the second insertion through-hole 31g.

Further, the processing container 31 includes a shielding plate 42 that shields a space 311 between the first protrusion 31d and the second protrusion 31e on the side of the negative Y-axis direction. The shielding plate 42 includes a recess that is recessed toward the space 311, and an imager 41 and an illuminator 44, which are described later, are accommodated in the recess.

The shielding plate 42 includes an opening 42a at a position facing the loading/unloading port 31b across the space 311 for allowing the wafer W to pass through the opening 42a. In addition, the processing container 31 may include other shielding plates (not illustrated) that shield two side surfaces (herein, surfaces on sides of positive and negative X-axis directions) of the space 311.

As illustrated in FIGS. 3 and 6, the drying unit 18 includes the imager 41. The imager 41 captures an image of an imaging region including the loading/unloading port 31b and the processing space 31a within the processing container 31 exposed from the loading/unloading port 31b in a state where the loading/unloading port 31b is not closed by the lid 32.

The imager 41 is positioned so as not to overlap, in a plane view, with the transport path R of the wafer W to the processing space 31a via the loading/unloading port 31b. Specifically, the imager 41 is positioned adjacent to the opening 42a along a width direction (herein, the X-axis direction) of the transport path R of the wafer W on an outer surface of the shielding plate 42 that does not face the space 311.

The shielding plate 42 is formed with a through-hole 42b at a position adjacent to the opening 42a along the width direction of the transport path R of the wafer W. The through-hole 42b is blocked by a transparent member 42c. The imager 41 captures an image of the imaging region from the outer surface of the shielding plate 42 through the transparent member 42c.

In this way, the drying unit 18 according to the embodiment may appropriately detect an internal status of the processing container 31 by using the imager 41 to capture an image of the imaging region including the loading/unloading port 31b and the processing space 31a within the processing container 31 exposed from the loading/unloading port 31b. As a result, it is possible for the drying unit 18 to detect, for example, whether another wafer remains in the processing container 31 when loading the wafer W into the processing container 31, thus reducing a possibility of a damage to the wafer W caused by collision between the two wafers.

Further, since the imager 41 is positioned so as not to overlap the transport path R of the wafer W in a plane view, it is possible to avoid interference between the imager 41 and the wafer W even when the transport device 16 loads the wafer W from the loading/unloading port 31b into the processing space 31a.

Further, the imager 41 captures an image of the imaging region from the outer surface of the shielding plate 42 via the transparent member 42c. In this way, it is possible for the imager 41 to perform the imaging process without contact between the imager 41 and an internal atmosphere of the space 311 between the first and second protrusions 31d and 31e, thereby preventing a failure of the imager 41 caused by contact with the internal atmosphere of the space 311.

A partition wall 43 is disposed on the shielding plate 42. The partition wall 43 is positioned on the outer surface of the shielding plate 42 to surround an outer periphery of the opening 42a, thereby isolating the opening 42a from the imager 41. In this way, it is possible for the imager 41 to perform the imaging process without contact between the imager 41 and the internal atmosphere of the space 311 between the first and second protrusions 31d and 31e, thereby preventing a failure of the imager 41 caused by contact with the internal atmosphere of the space 311.

As illustrated in FIGS. 3 to 5, the drying unit 18 includes the illuminator 44. The illuminator 44 illuminates at least a predetermined region around the loading/unloading port 31b within the imaging region captured by the imager 41. Specifically, the illuminator 44 illuminates a predetermined region located above the loading/unloading port 31b within the imaging region. For example, if the entire imaging region captured by the imager 41 were illuminated, reflected light from the imaging region could interfere with the imaging process by the imager 41, thus leading to a reduction in imaging accuracy of the imaging process.

In contrast, the drying unit 18 according to the embodiment illuminates, by using the illuminator 44, at least a predetermined region around the loading/unloading port 31b within the imaging region, rather than the entire imaging region. Therefore, the reflected light from the imaging region is reduced, making it possible to improve the imaging accuracy of the imaging process by the imager 41, and consequently, enabling more appropriate detection of the internal status of the processing container 31.

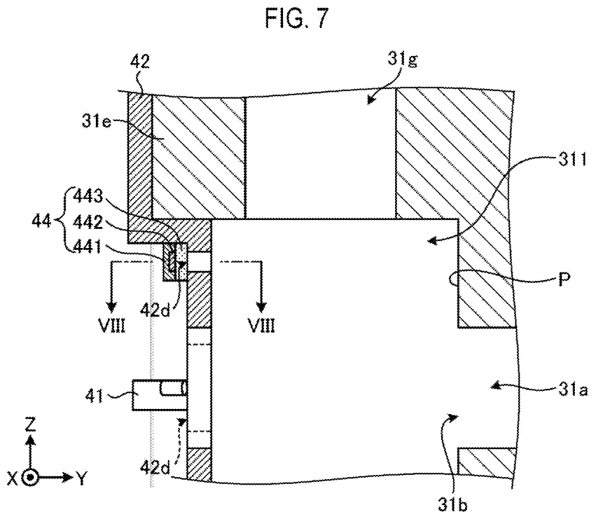

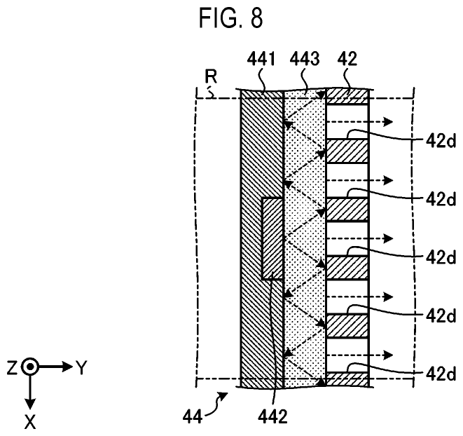

Herein, a configuration of the illuminator 44 and its surroundings is described with reference to FIGS. 7 and 8. FIG. 7 is an enlarged view illustrating the configuration of the illuminator 44 and its surroundings according to the embodiment. FIG. 8 is a cross-sectional view taken along line VIII-VIII in FIG. 7. In addition, for convenience of description, the partition wall 43 on the shielding plate 42 is omitted in FIG. 7.

As illustrated in FIGS. 7 and 8, the shielding plate 42 includes through-holes 42d arranged along the width direction (herein, the X-axis direction) of the transport path R of the wafer W at a position facing a predetermined region P around the loading/unloading port 31b illuminated by the illuminator 44.

The illuminator 44 includes a fixing plate 441, a light source 442, and a light diffuser 443 The fixing plate 441 is a plate-shaped member extending in the width direction of the transport path R of the wafer W, and faces the through-holes 42d in the shielding plate 42. The fixing plate 441 is connected to the shielding plate 42, for example, by a connecting member (not illustrated) such as a bolt or the like, with the light diffuser 443 interposed between the fixing plate 441 and the shielding plate 42. A recess is formed on a surface of the fixing plate 441 facing the shielding plate 42 to fix the light source 442.

The light source 442 is fixed to the fixing plate 441 and emits light. The light source 442 is fixed, for example, to a bottom surface of the recess formed in the fixing plate 441.

The light diffuser 443 is a plate-shaped member extending in the width direction of the transport path R of the wafer W, and is located between the fixing plate 441 and the shielding plate 42. The light diffuser 443 diffuses light emitted from the light source 442 in the width direction of the transport path R of the wafer W, and also irradiates the predetermined region P around the loading/unloading port 31b with a portion of the diffused light via the through-holes 42d.

In this way, the illuminator 44 of the embodiment diffuses the light in the width direction of the transport path R of the wafer W by using the light diffuser 443 and irradiates the predetermined region P around the loading/unloading port 31b with a portion of the diffused light via the through-holes 42d. Therefore, it is possible to evenly illuminate the entire predetermined region P around the loading/unloading port 31b.

As illustrated in FIGS. 3 to 5, the drying unit 18 includes the lock member 51. The lock member 51 is inserted through the first insertion through-hole 31f formed in the first protrusion 31d. An elevator 51a is connected to the lock member 51 for moving the lock member 51 up and down.

Herein, an operation of the lock member 51 is described. The drying unit 18 first performs the loading of the wafer W. In the wafer loading, the transport device 16 transfers the wafer W held by the wafer holder to the support pins 34. Then, the drying unit 18 rotates the lid 32 from the standby position (see FIG. 3) to the open position (see FIG. 4) using the rotator 32a, and also moves the lid 32 from the open position to the closed position (see FIG. 5) using the linear mover 32b. Therefore, the loading/unloading port 31b of the processing container 31 is closed by the lid 32, and the processing space 31a is sealed. Thereafter, the drying unit 18 raises the lock member 51 using the elevator 51a, so that the lock member 51 is inserted through the second insertion through-hole 31g formed in the second protrusion 31e.

The lock member 51, inserted into the second insertion through-hole 31g, comes into contact with a surface of the lid 32 opposite to a surface that closes the loading/unloading port 31b, thereby restricting the movement of the lid 32 from the closed position to the open position. Therefore, the lock member 51 may press the lid 32 toward the processing space 31a against the internal pressure generated by the supercritical fluid supplied into the processing space 31a. This allows the sealed state of the processing space 31a by the lid 32 to be maintained.

The drying unit 18 includes an exhaust duct 52. The exhaust duct 52 is located above the second insertion through-hole 31g. The exhaust duct 52 communicates with the space 311 between the first protrusion 31d and the second protrusion 31e via an exhaust hole (not illustrated) formed in the second protrusion 31e. The exhaust duct 52 is connected to a pump (not illustrated) and exhausts an atmosphere of the processing space 31a via the space 311 and the exhaust hole.

The exhaust duct 52 has through-holes 52a and 52b formed at a position corresponding to the second insertion through-hole 31g. The through-hole 52a is formed at a bottom of the exhaust duct 52, and the through-hole 52b is formed at a ceiling of the exhaust duct 52. Each of the through-holes 52a and 52b is blocked by a transparent member 52c.

The drying unit 18 includes an additional imager 53. The additional imager 53 captures an image of the sealing member 321 in a state where the loading/unloading port 31b is not closed by the lid 32. Specifically, when the lid 32 is located at the standby position, the additional imager 53 captures an image of the sealing member 321 from above the exhaust duct 52 via the transparent member 52c and the second insertion through-hole 31g.

In this way, it is possible for the drying unit 18 according to the embodiment to appropriately detect an abnormality of the sealing member 321 by using the additional imager 53 to capture an image of the sealing member 321. This makes it possible to prevent leakage of the processing fluid from the processing container 31 caused by deterioration of the sealing member 321.

In this way, it is possible for the drying unit 18 according to the embodiment to appropriately detect the internal status of the processing container 31 by using the imager 41 to capture an image of the imaging region including the loading/unloading port 31b and the processing space 31a within the processing container 31 exposed from the loading/unloading port 31b. As a result, it is possible for the drying unit 18 to detect, for example, whether another wafer remains in the processing container 31 when loading the wafer W into the processing container 31, thus reducing the possibility of a damage to the wafer W caused by collision between the two wafers.

### Specific Operation of Substrate Processing Apparatus

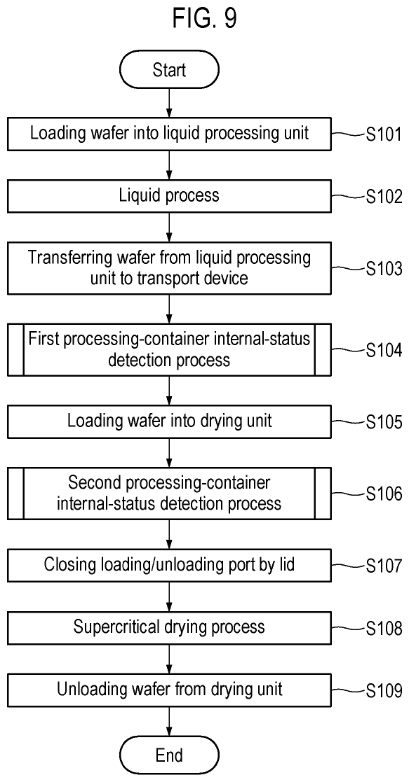

Next, a specific operation of the substrate processing apparatus 1 is described with reference to FIGS. 9 to 12. FIG. 9 is a flowchart illustrating a sequence of a process executed by the substrate processing apparatus 1 according to the embodiment. In addition, FIG. 9 illustrates an example of process sequences from when the wafer W is loaded into the liquid processing unit 17 until the wafer W is unloaded from the drying unit 18. Each process sequence illustrated in FIG. 9 is executed under the control of the controller 71.

In the substrate processing apparatus 1, first, the transport device 13 takes out the wafer W accommodated in the carrier C and places it on the deliverer 14. Next, the transport device 16 takes out the wafer W from the deliverer 14 and then, loads the wafer W into the liquid processing unit 17 (step S101).

Next, in the substrate processing apparatus 1, the liquid processing unit 17 performs a liquid process on the wafer W (step S102). Specifically, the liquid processing unit 17 performs a cleaning process on the front surface of the wafer W by using a chemical liquid or a rinse liquid, and then, performs a liquid film formation process in which an IPA liquid is supplied to the front surface of the wafer W to form a liquid film.

Next, in the substrate processing apparatus 1, the wafer W, which has undergone the liquid process, i.e., the wafer W on which the liquid film has been formed, is transferred from the liquid processing unit 17 to the transport device 16 (step S103).

Next, the substrate processing apparatus 1 performs a first processing-container internal-status detection process (step S104). Details of the first processing-container internal-status detection process are described later.

Next, the substrate processing apparatus 1 loads the wafer W into the drying unit 18 (step S105).

Specifically, the transport device 16 unloads the wafer W from the liquid processing unit 17 while holding the wafer W using the wafer holder. Then, the transport device 16 loads the wafer W, held by the wafer holder, from the loading/unloading port 31b of the drying unit 18 into the processing space 31a within the processing container 31. Then, the transport device 16 transfers the wafer W onto the support pins 34 within the processing container 31. Thereafter, the transport device 16 retracts the wafer holder.

Next, the substrate processing apparatus 1 performs a second processing-container internal-status detection process (step S106). Details of the second processing-container internal-status detection process are described later.

Next, in the substrate processing apparatus 1, the drying unit 18 closes the loading/unloading port 31b by using the lid 32 (step S107).

Specifically, the drying unit 18 rotates the lid 32 from the standby position (see FIG. 3) to the open position (see FIG. 4) by using the rotator 32a, and also moves the lid 32 from the open position to the closed position (see FIG. 5) by using the linear mover 32b. Therefore, the loading/unloading port 31b of the processing container 31 is closed by the lid 32, and the processing space 31a is sealed. Thereafter, the drying unit 18 raises the lock member 51 by using the elevator 51a, so that the lock member 51 is inserted into the second insertion through-hole 31g formed in the second protrusion 31e.

Next, the substrate processing apparatus 1 performs a supercritical drying process (step S108). Specifically, the drying unit 18 dries the wafer W, which has undergone the liquid film formation process, by bringing the wafer W into contact with a supercritical-state processing fluid.

Next, in the substrate processing apparatus 1, the transport device 16 unloads the wafer W from the drying unit 18 (step S109). Specifically, the transport device 16 holds the wafer W, which has undergone the supercritical drying process, by using the wafer holder, and unloads the held wafer W from the drying unit 18. Thereafter, the transport device 16 places the wafer W onto the deliverer 14, and the transport device 13 takes out the wafer W from the deliverer 14 and returns it to the carrier C. Therefore, a series of substrate processing for one wafer W is terminated.

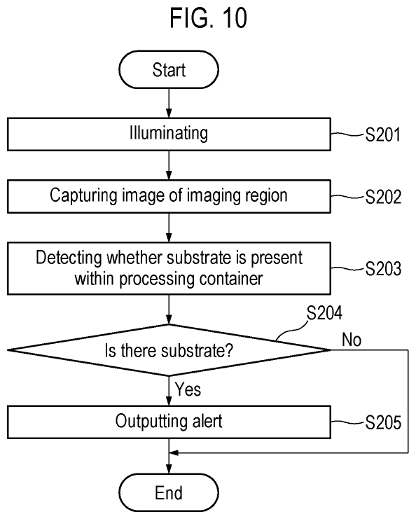

Next, the details of the first processing-container internal-status detection process in step S104 are described with reference to FIG. 10. FIG. 10 is a flowchart illustrating a sequence of the first processing-container internal-status detection process according to the embodiment. The first processing-container internal-status detection process illustrated in FIG. 10 is executed before step S105, i.e., before the wafer W is loaded into the processing space 31a via the loading/unloading port 31b.

The controller 71 illuminates the predetermined region P around the loading/unloading port 31b within the imaging region by using the illuminator 44 (step S201).

Next, the controller 71 captures an image of the imaging region by using the imager 41 (step S202). Specifically, the controller 71 captures an image of the imaging region including the loading/unloading port 31b and the processing space 31a within the processing container 31 exposed from the loading/unloading port 31b in a state where the loading/unloading port 31b is not closed by the lid 32.

Next, the controller 71 detects whether the wafer W is present within the processing container 31 based on an imaging result from the imager 41 (step S203). Specifically, the controller 71 obtains a brightness distribution inside the loading/unloading port 31b from the image captured by the imager 41, and when a maximum value of the obtained brightness distribution is greater than or equal to a threshold, the controller 71 detects that the wafer W is present within the processing container 31.

When it is detected that the wafer W is present within the processing container 31 (step S204, “YES”), the controller 71 outputs an alert (step S205) and terminates the process.

On the other hand, when it is detected that the wafer W is not present within the processing container 31 (step S204, “NO”), the controller 71 terminates the process without outputting an alert.

Further, when the controller 71 detects that the wafer W is present within the processing container 31, the controller 71 may stop the execution of the supercritical drying process, in addition to outputting an alert. For example, the controller 71 may stop the process after step S105 in FIG. 9, in addition to outputting an alert.

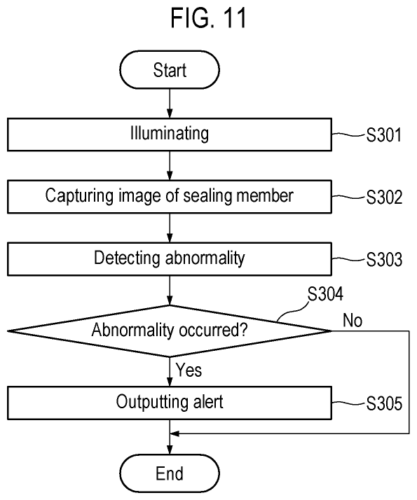

Further, in the substrate processing apparatus 1, a sealing member abnormality detection process may be performed in parallel with the second processing-container internal-status detection process. FIG. 11 is a flowchart illustrating a sequence of the sealing member abnormality detection process according to the embodiment.

The controller 71 illuminates, by using the illuminator 44, the predetermined region P around the loading/unloading port 31b within the imaging region (step S301). When the predetermined region P around the loading/unloading port 31b is illuminated, the lid 32 located at the standby position is irradiated with the reflected light from the predetermined region P. Therefore, the sealing member 321 provided on the lid 32 may be illuminated.

Next, the controller 71 captures an image of the sealing member 321 using the additional imager 53 (step S302). Specifically, the controller 71 captures an image of the sealing member 321 in a state where the loading/unloading port 31b is not closed by the lid 32.

Next, the controller 71 detects any abnormality in the sealing member 321 based on an imaging result from the additional imager 53 (step S303). Specifically, the controller 71 obtains a brightness distribution of the sealing member 321 from the image captured by the additional imager 53, and, based on the obtained brightness distribution, identifies a protruding portion extending from a peripheral edge of the sealing member 321. Then, when a length of the protruding portion is greater than or equal to a threshold, the controller 71 detects that an abnormality has occurred in the sealing member 321.

When the controller 71 detects that an abnormality has occurred in the sealing member 321 (step S304, “YES”), the controller 71 outputs an alert (step S305) and terminates the process.

On the other hand, when the controller 71 detects that no abnormality has occurred in the sealing member 321 (step S304, “NO”), the controller 71 terminates the process without outputting an alert.

Further, when the controller 71 detects an abnormality in the sealing member 321, the controller 71 may stop the execution of the supercritical drying process, in addition to outputting an alert. For example, the controller 71 may stop the process after step S105 in FIG. 9, in addition to outputting an alert.

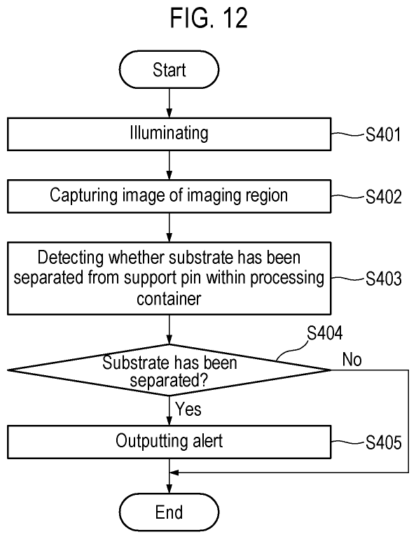

Next, the details of the second processing-container internal-status detection process in step S106 are described with reference to FIG. 12. FIG. 12 is a flowchart illustrating a sequence of the second processing-container internal-status detection process according to the embodiment. The second processing-container internal-status detection process illustrated in FIG. 12 is executed after the wafer W has been loaded into the processing space 31a via the loading/unloading port 31b and before the loading/unloading port 31b is closed by the lid 32.

The controller 71 illuminates, by using the illuminator 44, the predetermined region P around the loading/unloading port 31b within the imaging region (step S401).

Next, the controller 71 captures an image of the imaging region by using the imager 41 (step S402). Specifically, the controller 71 captures an image of the imaging region including the loading/unloading port 31b and the processing space 31a within the processing container 31 exposed from the loading/unloading port 31b in a state where the loading/unloading port 31b is not closed by the lid 32.

Next, the controller 71 detects whether the wafer W has been separated from the support pins 34 within the processing container 31 based on an imaging result from the imager 41 (step S403). Specifically, the controller 71 obtains a brightness distribution inside the loading/unloading port 31b from the image captured by the imager 41, and identifies a position inside the loading/unloading port 31b corresponding to a maximum value of the obtained brightness distribution as a peripheral edge position of the wafer W. Then, the controller 71 detects that the wafer W has been separated from the support pins 34 within the processing container 31 when the identified peripheral edge position of the wafer W deviates from a normal range.

When the controller 71 detects that the wafer W has been separated from the support pins 34 within the processing container 31 (step S404, “YES”), the controller 71 outputs an alert (step S405) and terminates the process.

On the other hand, when the controller 71 detects that the wafer W has not been separated from the support pins 34 within the processing container 31 (step S404, “NO”), the controller 71 terminates the process without outputting an alert.

In addition, when the controller 71 detects that the wafer W has been separated from the support pins 34 within the processing container 31, the controller 71 may stop the execution of the supercritical drying process, in addition to outputting an alert. For example, the controller 71 may stop the process after step S107 in FIG. 9, in addition to outputting an alert.

As described above, a substrate processing apparatus (e.g., the substrate processing apparatus 1) according to the embodiment includes a processing container (e.g., the processing container 31), a lid (e.g., the lid 32), and an imager (e.g., the imager 41). The processing container includes a processing space (e.g., the processing space 31a) capable of accommodating a substrate (e.g., the wafer W) and a loading/unloading port (e.g., the loading/unloading port 31b) through which the substrate is loaded into or unloaded from the processing space. The lid is configured to be capable of closing the loading/unloading port of the processing container. The imager captures an image of an imaging region including the loading/unloading port and the processing space within the processing container exposed from the loading/unloading port, in a state where the loading/unloading port is not closed by the lid.

Therefore, according to the substrate processing apparatus of the embodiment, it is possible to appropriately detect an internal status of the processing container.

### Others

In the above-described embodiment, an example has been described in which the imager 41 is positioned so as not to overlap with the transport path R of the wafer W in a plane view, but the imager 41 may be configured to be movable between an imaging position on the transport path R of the wafer W and a retracted position from the transport path R of the wafer W. In this case, the imager 41 moves from the retracted position to the imaging position to capture an image of the imaging region at the imaging position before the wafer W is loaded into the processing space 31a through the loading/unloading port 31b.

Further, the imager 41 may be provided on the transport device 16. In this case, the transport device 16 first loads the wafer W from the loading/unloading port 31b of the drying unit 18 into the processing space 31a within the processing container 31. The imager 41 provided on the transport device 16 captures an image of the imaging region before the loading/unloading port is closed by the lid 32.

According to the present disclosure, it is possible to appropriately detect an internal status of a processing container.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus comprising:
a processing container including a processing space capable of accommodating a substrate and a loading/unloading port through which the substrate is loaded into or unloaded from the processing space;
a lid configured to be capable of closing the loading/unloading port; and
an imager configured to capture an image of an imaging region including the loading/unloading port and the processing space within the processing container exposed from the loading/unloading port, in a state where the loading/unloading port is not closed by the lid.

2. The substrate processing apparatus of claim 1, wherein the imager is positioned so as not to overlap, in a plane view, with a transport path of the substrate to the processing space via the loading/unloading port.

3. The substrate processing apparatus of claim 2, wherein the processing container includes:
a first protrusion protruding from the loading/unloading port below the loading/unloading port toward a side of an unloading direction of the substrate with respect to the processing space;
a second protrusion protruding from the loading/unloading port above the loading/unloading port toward the side of the unloading direction of the substrate with respect to the processing space; and
a shielding plate configured to shield a space between the first protrusion and the second protrusion,
wherein the shielding plate includes an opening at a position facing the loading/unloading port across the space between the first protrusion and the second protrusion, the opening allowing the substrate to pass through the opening, and
wherein the imager is positioned adjacent to the opening along a width direction of the transport path of the substrate on an outer surface of the shielding plate that does not face the space between the first protrusion and the second protrusion.

4. The substrate processing apparatus of claim 3, wherein the shielding plate includes:
a through-hole formed at a position adjacent to the opening along the width direction of the transport path of the substrate; and
a transparent member blocking the through-hole, and
wherein the imager captures the image of the imaging region from the outer surface of the shielding plate via the transparent member.

5. The substrate processing apparatus of claim 3, wherein the shielding plate includes a partition wall positioned on the outer surface of the shielding plate to surround an outer periphery of the opening, so as to isolate the opening from the imager.

6. The substrate processing apparatus of claim 3, further comprising an illuminator configured to illuminate at least a predetermined region around the loading/unloading port within the imaging region captured by the imager.

7. The substrate processing apparatus of claim 6, wherein the shielding plate includes through-holes arranged along the width direction of the transport path of the substrate at a position facing the predetermined region around the loading/unloading port, and
wherein the illuminator includes:
a fixing plate facing the through-holes in the shielding plate;
a light source fixed to the fixing plate; and
a light diffuser located between the fixing plate and the shielding plate and configured to diffuse light emitted from the light source in the width direction of the transport path of the substrate and to irradiate the predetermined region around the loading/unloading port with a portion of the diffused light through the through-holes.

8. The substrate processing apparatus of claim 1, further comprising a controller configured to capture the image of the imaging region by using the imager before loading of the substrate into the processing space via the loading/unloading port is performed, and to detect whether the substrate is present within the processing container based on an imaging result from the imager.

9. The substrate processing apparatus of claim 8, wherein the processing container includes a support pin provided on a bottom surface of the processing space to support the substrate, and
wherein the substrate processing apparatus further comprises a controller configured to capture the image of the imaging region by using the imager after loading of the substrate into the processing space via the loading/unloading port is performed and before the loading/unloading port is closed by the lid, and to detect whether the substrate has been separated from the support pin within the processing container based on the imaging result from the imager.

10. The substrate processing apparatus of claim 1, wherein the lid is configured to be movable between a closed position where the lid closes the loading/unloading port via a sealing member and an open position spaced apart from the closed position in an unloading direction of the substrate from the processing space, and
wherein the substrate processing apparatus further comprises a lock member configured to be inserted through an insertion through-hole of the processing container and come into contact with a surface of the lid opposite to a lid surface that closes the loading/unloading port, so as to restrict movement of the lid from the closed position to the open position.

11. The substrate processing apparatus of claim 10, further comprising an additional imager configured to capture an image of the sealing member in a state where the loading/unloading port is not closed by the lid,
wherein the lid is configured to be rotatable between the open position and a standby position where a portion of the sealing member faces the insertion through-hole, and
wherein the additional imager captures the image of the sealing member through the insertion through-hole from above the insertion through-hole when the lid is located at the standby position.

12. The substrate processing apparatus of claim 11, further comprising an exhaust duct located above the insertion through-hole and configured to exhaust the processing space within the processing container,
wherein the exhaust duct includes a through-hole formed at a position corresponding to the insertion through-hole, and a transparent member blocking the through-hole, and
wherein the additional imager captures the image of the sealing member through the transparent member and the insertion through-hole from above the exhaust duct when the lid is located at the standby position.

13. The substrate processing apparatus of claim 11, further comprising a controller configured to capture the image of the sealing member by using the additional imager before loading of the substrate into the processing space via the loading/unloading port is performed, and to detect an abnormality of the sealing member based on an imaging result from the additional imager.

14. A method of detecting an internal status of a processing container in a substrate processing apparatus, the substrate processing apparatus comprising the processing container including a processing space capable of accommodating a substrate and a loading/unloading port through which the substrate is loaded into or unloaded from the processing space, a lid configured to be capable of closing the loading/unloading port of the processing container, and an imager configured to capture an image of an imaging region including the loading/unloading port and the processing space within the processing container exposed from the loading/unloading port, in a state where the loading/unloading port is not closed by the lid, the method comprising:
capturing the image of the imaging region by using the imager before loading of the substrate into the processing space through the loading/unloading port is performed; and
detecting whether the substrate is present within the processing container based on an imaging result from the imager.
